(19) United States
(12) Patent Application Publication
(10) Pub. No.: US 2025/0336663 A1
(43) Pub. Date: Oct. 30, 2025

(54) IRRADIATION UNIT, LAMP UNIT, AND LAMP HOLDER

(71) Applicant: Ushio Denki Kabushiki Kaisha, Tokyo (JP)

(72) Inventors: Kunio KASAGI, Tokyo (JP); Hajime ISHIHARA, Tokyo (JP); Shinji YAMASHITA, Tokyo (JP)

(73) Assignee: Ushio Denki Kabushiki Kaisha, Tokyo (JP)

(21) Appl. No.: 18/729,358

(22) PCT Filed: Oct. 31, 2022
(86) PCT No.: PCT/JP2022/040578

§ 371 Date: Dec. 24, 2024

(30) Foreign Application Priority Data
Jan. 25, 2022 (JP) 2022-009536

(51) Int. Cl. H01J 61/02; B08B 7/00; B41J 11/00; G03F 7/20; H01J 61/56; H01L 21/67

(52) U.S. Cl. CPC H01J 61/025; H01J 61/56; B08B 7/0057; B41J 11/00214; B41J 11/00218; G03F 7/2002; H01L 21/67115

(57) ABSTRACT

The purpose of the present invention is to provide an irradiation unit and a lamp unit in which the risk of damaging a lamp is reduced due to simplified replacement of the lamp. The present invention includes: a lamp unit on which an excimer lamp is mounted, the excimer lamp having a light-emitting tube that extends in a first direction and a first electrode and a second electrode that are arranged to face each other in a radial direction of the light-emitting tube; and a housing which accommodates the excimer lamp due to the lamp unit being inserted therein, the lamp unit includes a plate material, a restriction member which protrudes from a first main surface and restricts movement of the excimer lamp inside the housing, and a power supply portion that is disposed on a second main surface side of the plate material positioned outside of the housing and that supplies electric power to the excimer lamp when the plate material closes an insertion opening.

### TECHNICAL FIELD

The present invention relates to an irradiation unit, a lamp unit mounted on the irradiation unit, and a lamp holder mounted on the irradiation unit.

### BACKGROUND ART

Conventionally, a technique of irradiating a semiconductor wafer, a display panel, or the like with ultraviolet light to perform dry cleaning, and a technique of irradiating a printed matter with ultraviolet light to perform ink curing are known. An ultraviolet irradiation device that irradiates a semiconductor wafer placed at a predetermined position with ultraviolet light, an ultraviolet irradiation device that irradiates a sequentially conveyed printed matter with ultraviolet light, and the like are known. For example, Patent Document 1 below describes an ultraviolet irradiation device used for ink drying in printing technologies, fine exposure in semiconductor technologies, curing of an adhesive in liquid-crystal technologies, and the like.

### PRIOR ART DOCUMENT

### Patent Document

Patent Document 1: JP-A-2011-177625

### SUMMARY OF THE INVENTION

### Problems to be Solved by the Invention

In recent years, an ultraviolet irradiation device may be equipped with a long-shape ultraviolet lamp having a total length of more than 1 m so as to irradiate a large workpiece (for example, a display panel or the like) with ultraviolet light.

However, the long-shape ultraviolet lamp is very heavy and has poor operability, and thus, it is difficult to carry the ultraviolet lamp in a narrow passage and to replace the ultraviolet lamp in a narrow space. For this reason, when an operator maintains the ultraviolet irradiation device, he/she may hit the ultraviolet lamp at a wall surface or the like of the ultraviolet irradiation device, and may drop the ultraviolet lamp on the floor in some cases. The above-described problem is particularly likely to occur particularly in a case where the operator needs to crawl into the ultraviolet irradiation device, or in a case where a working space is not sufficiently ensured due to the ultraviolet irradiation device being installed at a corner of a workplace.

In view of this, Patent Document 1 proposes an ultraviolet irradiation device in which an ultraviolet lamp can be pulled out from a lamp house by a member called a carrier and replaced outside the lamp house in order to facilitate the replacement of the ultraviolet lamp.

However, the ultraviolet irradiation device described in Patent Document 1 needs a step for detaching an old ultraviolet lamp to be replaced from a hook and a step for engaging a new ultraviolet lamp with the hook and fixing the new ultraviolet lamp with a retaining member, in addition to the step for inserting and removing the ultraviolet lamp by the carrier. For this reason, in the ultraviolet irradiation device having the above configuration, an operator may hit the ultraviolet lamp at the inner wall surface of the lamp house or the hook and damage the ultraviolet lamp at the time of replacing the ultraviolet lamp.

In view of the above problem, the purpose of the present invention is to provide an irradiation unit and a lamp unit in which the risk of damaging a lamp is reduced due to simplified replacement of the lamp.

### Means for Solving the Problems

An irradiation unit according to the present invention includes:
an excimer lamp that has a long shape extending in a first direction;
a lamp holder on which the excimer lamp is mounted;
a housing having an insertion opening and receiving the lamp holder through the insertion opening;
a light extraction portion provided in the housing and extracting ultraviolet light emitted from the excimer lamp mounted on the lamp holder to an outside of the housing;
a plate material provided on the lamp holder and closing the insertion opening;
a restriction member that restricts movement of the excimer lamp in the housing, the restriction member being formed so as to protrude from a first main surface located inside the housing among main surfaces of the plate material in a state where the plate material closes the insertion opening; and
a power supply portion that is provided on a side of a second main surface of the plate material located outside the housing and that supplies electric power to the excimer lamp in a state where the plate material closes the insertion opening.

The excimer lamp is a dielectric barrier discharge lamp having a light-emitting tube in which a light-emitting gas is sealed, and emits light having a wavelength corresponding to the discharge gas by applying a voltage between electrodes. Examples of the shape of the excimer lamp include a shape called a single tube shape or a double tube shape including a cylindrical light-emitting tube, and a shape called a flat tube shape in which a cross-sectional shape along a plane orthogonal to a tube axis is rectangular. The excimer lamp mounted on the irradiation unit according to the present invention may have any shape.

In the present specification, “being electrically connected” means being directly connected or being indirectly connected via a metal plate, a lead wire, a circuit component such as a resistance element or a transformer, etc. to establish a state in which electric current is passed between the components.

When there is no portion on which a person puts his/her finger on the plate material or the like, it is difficult to remove, from the housing, the lamp unit that is inserted into the housing. In view of this, the above configuration is employed, whereby an operator or a robot can remove the excimer lamp from the irradiation unit by pulling the lamp unit from the housing. Then, the operator or the robot can replace the excimer lamp mounted on the lamp unit after moving the lamp unit in a space where the operator or the robot easily works.

Then, after the lamp unit in which the excimer lamp has been replaced is inserted from the insertion opening of the housing, the power supply portion disposed on the second main surface side of the plate material, that is, on the outer side of the housing is connected to a power supply device, whereby the attachment to the irradiation unit is completed.

In addition, both end parts of the excimer lamp are supported by a pair of restriction members provided on the plate material. Thus, the center of gravity of the light-emitting tube is closer to the operator and thus operability is improved as compared with a case where work is performed with one end of the excimer lamp being held.

As a result, according to the irradiation unit having the above configuration, a sufficiently wide space for the replacement of the excimer lamp can be ensured, and it is not necessary to frequently move the excimer lamp in the housing or adjust the position, so that the risk of damaging the excimer lamp during a maintenance operation or the like is reduced.

In the irradiation unit described above,
the excimer lamp may include a light-emitting tube having a pair of flat outer wall surfaces facing each other, and a first electrode and a second electrode that are formed on the pair of outer wall surfaces of the light-emitting tube so as to face each other across the light-emitting tube.

For dry cleaning of a semiconductor wafer or a display panel, ultraviolet light with a wavelength of 100 nm to 200 nm that is highly effective in decomposition of dirt such as oil is often used. Ultraviolet light having such a wavelength band is easily absorbed by oxygen in the air, and thus, the propagation distance thereof in the air is about several mm to several cm. Therefore, it is preferable that the excimer lamp mounted on the irradiation unit is disposed as close as possible to an object to be irradiated (hereinafter referred to as “workpiece”).

The excimer lamp having the above configuration emits ultraviolet light from the flat surface of the light-emitting tube. Therefore, according to the irradiation unit having the above configuration, the excimer lamp can be placed close to a plate-shaped workpiece such as a semiconductor wafer or a display panel over a wide range. That is, the irradiation unit having the above configuration can suppress non-uniform irradiation of the plate-shaped workpiece described above with ultraviolet light.

In the irradiation unit described above,
the restriction member may include:
a base member that protrudes from the first main surface of the plate material in a second direction that is a normal direction of the first main surface;
a first columnar support protruding from the base member in a third direction orthogonal to the first direction and the second direction;
a second columnar support protruding from the base member in a direction same as the direction in which the first columnar support protrudes at a position farther from the plate material than the first columnar support; and
a first holding member and a second holding member that hold an end part of the excimer lamp between the first columnar support and the second columnar support,
the second holding member being fixed so as to connect the first columnar support and the second columnar support.

In addition, the irradiation unit described above may further include:
a conductive member made of a metal material, the conductive member being held between the first holding member and the excimer lamp and coming in contact with a first electrode that is one of a pair of electrodes included in the excimer lamp; and
a lead wire that electrically connects the second columnar support and a second electrode different from the first electrode of the excimer lamp, the lead wire being wired inside a groove or a through hole formed in the base member,
wherein the first holding member may be formed of a ceramic material, at least a part of the second holding member and the second columnar support may be formed of a metal material, and
when the first holding member and the second holding member are fixed while holding the excimer lamp, a first power supply portion included in the power supply portion and the first electrode may be electrically connected via the conductive member, and a second power supply portion that is different from the first power supply portion and that is included in the power supply portion and the second electrode may be electrically connected via the second holding member, the second columnar support, and the lead wire.

With the above configuration, in the lamp unit, the connection between the electrode and the power supply portion is completed only by holding the excimer lamp by the first holding member and the second holding member and fixing the second holding member to each columnar support. Therefore, wiring work when the excimer lamp is mounted on the lamp unit is unnecessary.

In addition, according to the above configuration, the lead wire connecting the second columnar support and the second power supply portion is protected by a ceramic material that hardly conducts electricity, and thus, occurrence of a leakage current and a short circuit during operation is suppressed.

In the irradiation unit described above,
the plate material may include a handle protruding from the second main surface.

According to the above configuration, the operator or the robot can easily pull out the lamp unit from the housing as compared with a lamp unit not provided with the handle.

The irradiation unit described above may further include:
a guide insertion portion formed in the housing and extending in a second direction that is a normal direction of the first main surface; and
a guide member provided on the plate material and extending in the second direction, the guide member being inserted into the guide insertion portion to restrict movement of the lamp holder.

According to the above configuration, the lamp unit is guided by the guide member and the guide insertion portion so as to be inserted in the second direction at a predetermined position of the housing, whereby the risk that the lamp unit is shifted in a direction different from the second direction or the risk that the housing and the excimer lamp accidentally collide with each other is further reduced. That is, the risk of damaging the light-emitting tube of the excimer lamp is further reduced.

In the irradiation unit described above,
the light extraction portion of the housing may be covered with a material that transmits ultraviolet light emitted from the excimer lamp, and an inner space of the housing may be enclosed by closing the insertion opening by the plate material due to the lamp holder being inserted.

According to the irradiation unit having the above configuration, the housing can be filled with an inert gas during operation, and absorption of ultraviolet light emitted from the excimer lamp in the housing by oxygen can be suppressed. Therefore, the irradiation unit having the above configuration can more efficiently irradiate the workpiece with ultraviolet light.

A lamp unit according to the present invention includes
the excimer lamp and the lamp holder applied to the irradiation unit described above.

Further, a lamp holder according to the present invention includes
a lamp holder included in the irradiation unit.

### Effect of the Invention

The present invention can provide an irradiation unit and a lamp unit in which the risk of damaging a lamp is reduced due to simplified replacement of the lamp.

### BRIEF DESCRIPTION OF THE DRAWINGS

FIG. 1 is a perspective view schematically illustrating an ultraviolet irradiation device according to one embodiment.

FIG. 2 is a perspective view illustrating a configuration of an irradiation unit.

FIG. 3 is a perspective view illustrating a state in which a lamp unit is being inserted into a housing.

FIG. 4 is a perspective view illustrating a configuration of the housing.

FIG. 5 is a perspective view illustrating a configuration of the lamp unit.

FIG. 6A is a diagram of an excimer lamp as viewed in a Y direction.

FIG. 6B is a cross-sectional view of the excimer lamp cut along a YZ plane.

FIG. 7 is a perspective view illustrating the lamp unit from which the excimer lamp and a restriction member are removed.

FIG. 8 is a diagram of the lamp unit as viewed in an X direction.

FIG. 9 is a diagram illustrating a state in which the restriction member is disassembled.

FIG. 10A is a diagram illustrating the periphery of a base member in FIG. 9.

FIG. 10B is a diagram illustrating the periphery of the base member in FIG. 9.

FIG. 11 is a perspective view schematically illustrating a lamp unit included in an irradiation unit according to another embodiment.

FIG. 12 is a perspective view schematically illustrating a lamp unit included in an irradiation unit according to still another embodiment.

### MODE FOR CARRYING OUT THE INVENTION

An irradiation unit, a lamp unit, and a lamp holder according to the present invention will be described below with reference to the drawings. Note that each of the drawings described below is schematically illustrated, and dimensional ratios or the numbers of components in the drawings do not necessarily coincide with the actual dimensional ratios or the actual number of components.

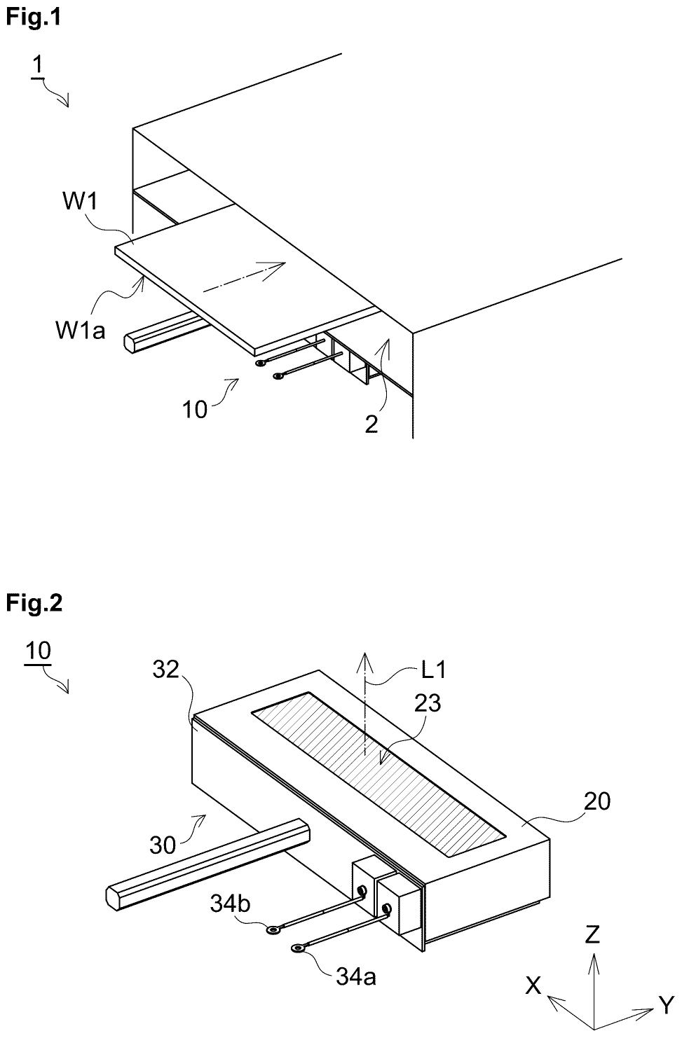

FIG. 1 is a perspective view schematically illustrating an ultraviolet irradiation device 1 according to one embodiment. As illustrated in FIG. 1, the ultraviolet irradiation device 1 includes a conveyance path 2 on which a workpiece W1 to be irradiated with ultraviolet light is conveyed, and an irradiation unit 10 that irradiates an irradiation surface W1a, which is one of main surfaces of the workpiece W1 conveyed in the conveyance path 2, with ultraviolet light.

FIG. 1 illustrates the workpiece W1 having a plate shape with a rectangular main surface for convenience of illustration, but the workpiece W1 to be irradiated with ultraviolet light by the ultraviolet irradiation device 1 is not limited to a member having the shape described above. Specifically, the ultraviolet irradiation device 1 may be configured to irradiate a semiconductor wafer or a film material, a printed matter, and the like sequentially conveyed with ultraviolet light.

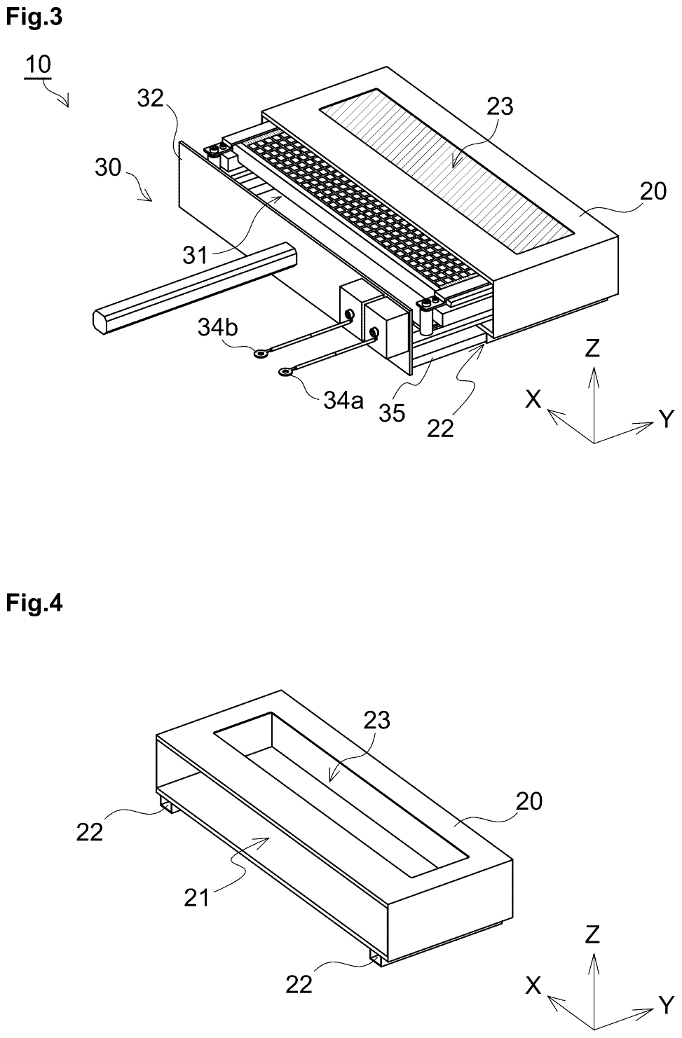

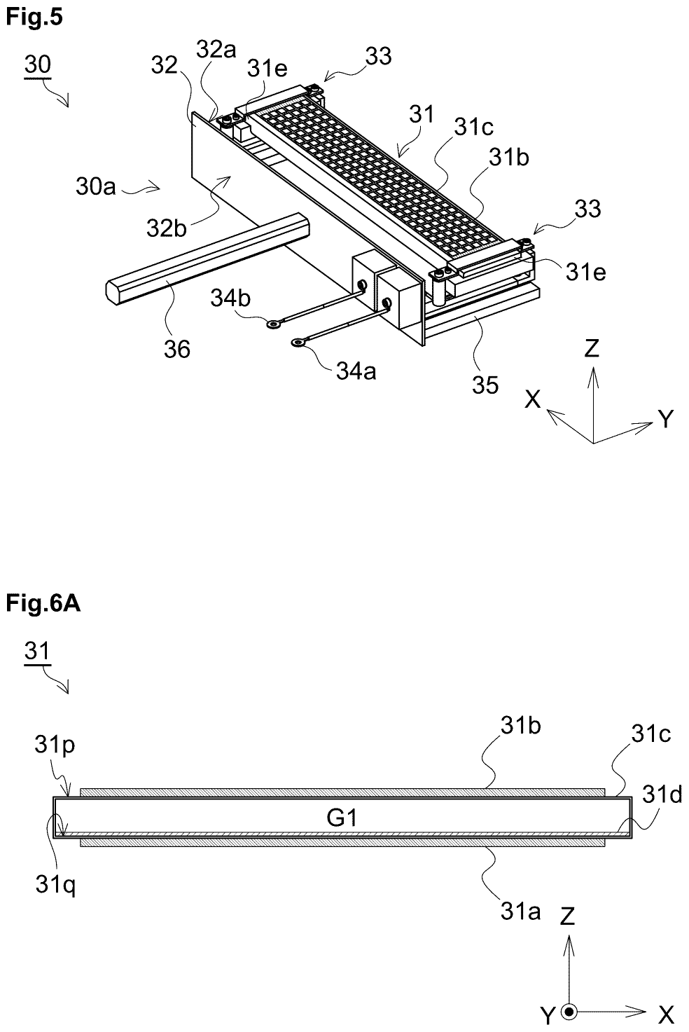

FIG. 2 is a perspective view illustrating the configuration of the irradiation unit 10, and FIG. 3 is a perspective view illustrating a state in which a lamp unit 30 is being inserted into a housing 20 in order to constitute the irradiation unit 10. FIG. 4 is a perspective view illustrating the configuration of the housing 20, and FIG. 5 is a perspective view illustrating the configuration of the lamp unit 30. Note that, in FIG. 4, a light extraction portion 23 to be described later is not hatched so that the structure inside the housing 20 can be easily confirmed.

The irradiation unit 10 includes the housing 20 and the lamp unit 30 as illustrated in FIGS. 2 and 3, and the lamp unit 30 is inserted into the housing 20 as illustrated in FIG. 3.

In the following description, a direction in which ultraviolet light L1 is emitted from the irradiation unit 10 is a Z direction as illustrated in FIG. 2, a direction in which the lamp unit 30 is inserted into the housing 20 is a Y direction as illustrated in FIG. 3, and a direction orthogonal to the Y direction and the Z direction is an X direction. The X direction corresponds to a “first direction”, the Y direction corresponds to a “second direction”, and the Z direction corresponds to a “third direction”.

Furthermore, positive and negative orientations distinguished from each other for directional expression will be described as a “+Z direction” and a “−Z direction” by adding positive and negative signs, while a direction expressed without distinction between positive and negative orientations will be described simply as the “Z direction”.

The housing 20 includes an insertion opening 21, a guide insertion portion 22, and the light extraction portion 23 as illustrated in FIG. 4. The light extraction portion 23 in the present embodiment is an emission window covered with quartz glass.

Note that the light extraction portion 23 may be an emission window covered with a material that transmits vacuum ultraviolet light, such as magnesium fluoride, in addition to quartz glass. In addition, the light extraction portion 23 may be a simple opening not covered with quartz glass or the like in a case where it is desired to decrease the distance between an excimer lamp 31 mounted on the lamp unit 30 and the workpiece W1 rather than to seal the housing 20 and fill the housing 20 with an inert gas.

As illustrated in FIG. 5, the lamp unit 30 includes the excimer lamp 31, a plate material 32, a pair of restriction members (33, 33), a first power supply portion 34a, a second power supply portion 34b, a guide member 35, and a handle 36. Note that a configuration obtained by removing the excimer lamp 31 from the components constituting the lamp unit 30 corresponds to a lamp holder 30a.

The excimer lamp 31 in the present embodiment is configured such that both end parts (31e, 31e) are supported by a pair of restriction members (33, 33) provided so as to protrude in the +Y direction from a first main surface 32a of the plate material 32, and a light-emitting tube 31c extends along the X direction.

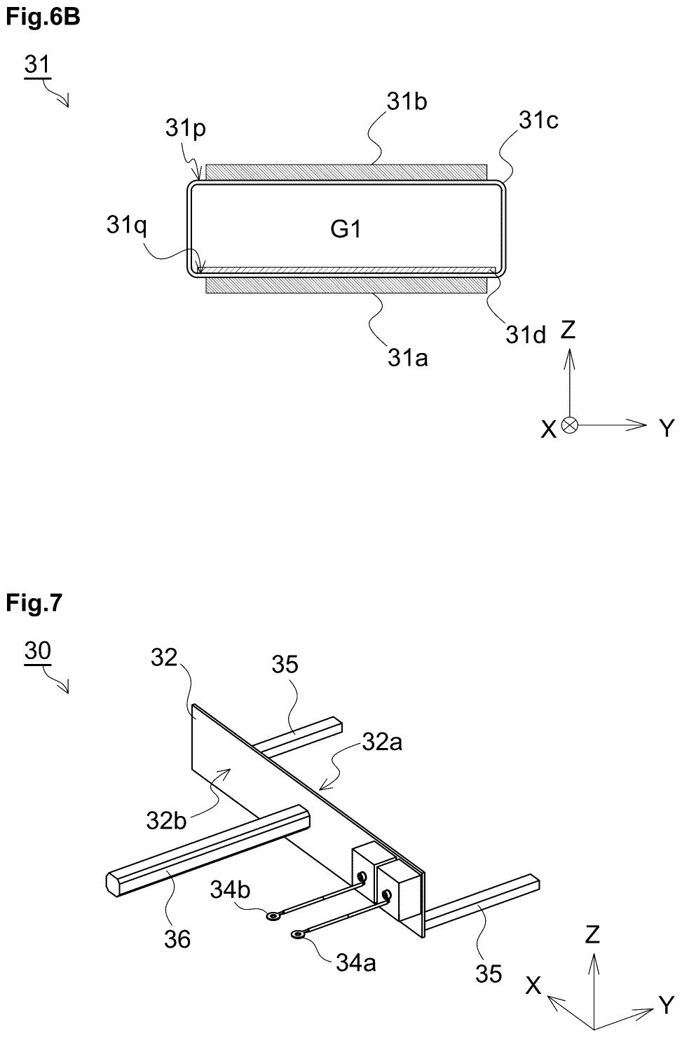

FIG. 6A is a diagram of the excimer lamp 31 viewed in the Y direction, and FIG. 6B is a cross-sectional view of the excimer lamp 31 cut along a YZ plane. As illustrated in FIG. 6B, the excimer lamp 31 has a rectangular cross-sectional shape when cut along the YZ plane, and a pair of electrodes (31b, 31c) facing each other in the Z direction (radial direction) across the light-emitting tube 31c is formed on flat outer wall surfaces 31p of the light-emitting tube 31c facing each other in the Z direction. In the present embodiment, the electrode on the −Z side corresponds to the first electrode 31a, and the electrode on the +Z side corresponds to the second electrode 31b.

The excimer lamp 31 according to the present embodiment contains a light-emitting gas G1 that includes Xe and that is sealed inside the light-emitting tube 31c having a length of 0.4 m in the X direction, and emits ultraviolet light having a main emission wavelength of 172 nm when being applied with a voltage between the first electrode 31a and the second electrode 31b. The “main emission wavelength” used herein refers to a wavelength showing a peak in an intensity spectrum.

An excimer lamp having a shape different from that of the excimer lamp 31 as illustrated in FIGS. 6A and 6B may be mounted in the lamp unit 30 according to the present embodiment. For example, an excimer lamp having a so-called single tube shape or double tube shape as described above may be mounted.

In addition, any gas is selectable as the light-emitting gas G1 sealed in the light-emitting tube 31c depending on the intended use. For example, a gas not containing Xe may be used as the light-emitting gas G1. In the irradiation unit 10, ultraviolet light emitted from the excimer lamp 31 preferably has a wavelength of 150 nm to 200 nm from the viewpoint of being able to decompose dirt such as oil and generating ozone.

Furthermore, in the excimer lamp 31 according to the present embodiment, a reflective membrane 31d made of silica (SiO2) is formed on an inner wall surface 31q of the light-emitting tube as illustrated in FIGS. 6A and 6B. The reflective membrane 31d reflects ultraviolet light generated in the light-emitting tube 31c and traveling to the −Z side to the +Z side. In a case where a desired treatment can be sufficiently performed with ultraviolet light generated in the light-emitting tube 31c and directly traveling to the +Z side, the excimer lamp 31 may not have the reflective membrane 31d.

When the lamp unit 30 is inserted into the housing 20, the plate material 32 closes the insertion opening 21 of the housing 20 and encloses the space inside the housing 20 as illustrated in FIG. 2. The housing 20 whose inner space is enclosed by the plate material 32 is filled with an inert gas (for example, nitrogen gas) during operation. Note that, in a case where, for example, the light extraction portion 23 is an opening without being covered with quartz glass or the like as described above, the housing 20 may not be closed by the plate material 32.

The first power supply portion 34a and the second power supply portion 34b are provided so as to be aligned on the second main surface 32b side (−Y side) of the plate material 32 as illustrated in FIG. 5. When the lamp unit 30 is inserted into the housing 20 as illustrated in FIG. 2, the first power supply portion 34a and the second power supply portion 34b are respectively connected to a high-voltage-side terminal and a low-voltage-side terminal of a power supply device (not shown) mounted on the ultraviolet irradiation device 1. Each of the first power supply portion 34a and the second power supply portion 34b may be located on the −Y side of the plate material 32 using a lead wire as illustrated in FIG. 5, or may be a power supply terminal provided so as to protrude from the second main surface 32b of the plate material 32 to the −Y side.

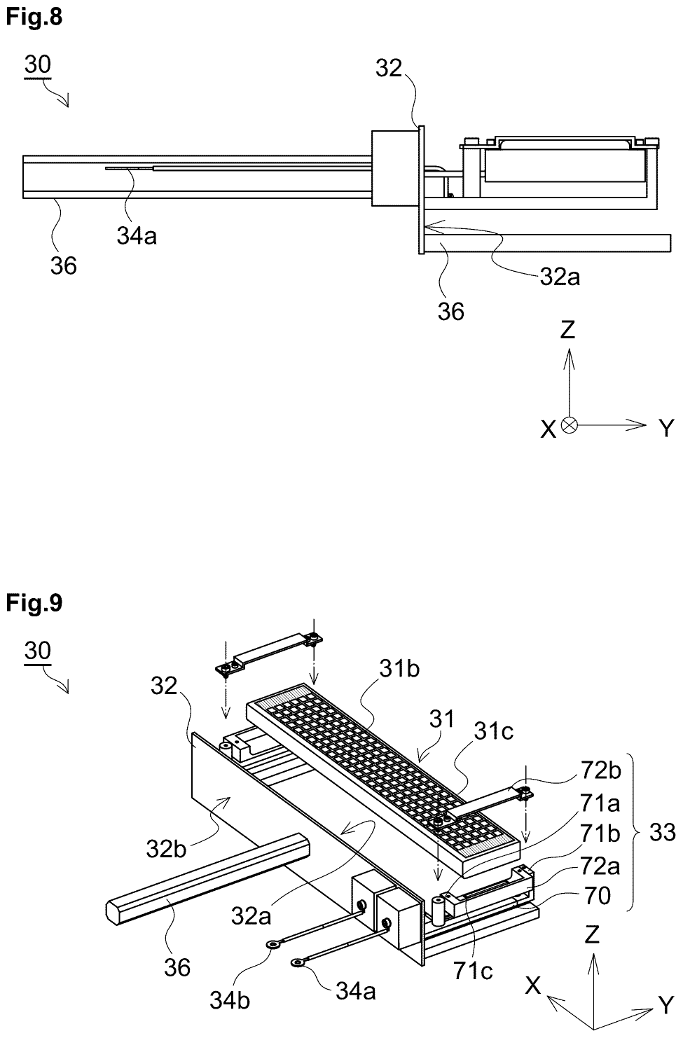

FIG. 7 is a perspective view of the lamp unit 30 from which the excimer lamp 31 and the restriction members 33 are removed, and FIG. 8 is a diagram of the lamp unit 30 as viewed from the X side. As illustrated in FIGS. 7 and 8, the guide member 35 in the present embodiment is a rod-shaped member provided so as to protrude in the +Y direction from the first main surface 32a of the plate material 32, and two guide members are provided apart from each other in the X direction. The housing 20 is provided with two guide insertion portions 22 separated from each other in the X direction as illustrated in FIG. 4.

With the configuration in which the guide members 35 are inserted into the guide insertion portions 22 of the housing 20, the lamp unit 30 is guided to a predetermined insertion position of the housing 20 and is inserted straight in the Y direction without swaying in the X direction or the Z direction as illustrated in FIG. 3.

Note that the configuration of the guide insertion portions 22 illustrated in FIG. 4 and the configuration of the guide members 35 illustrated in FIG. 7 are merely examples, and the shapes, the number, and the like of the guide members 35 and the guide insertion portions 22 are freely selected. In addition, in a case where, for example, the housing 20 is sufficiently large and there is no possibility that the excimer lamp 31 and the housing 20 come into contact with each other during insertion of the lamp unit 30, the guide member 35 and the guide insertion portion 22 may not be provided.

As illustrated in FIG. 5, the handle 36 is a rod-shaped member having a length of 200 mm and provided so as to protrude in the −Y direction from the second main surface 32b of the plate material 32, the handle 36 being a portion gripped by an operator with his/her hand when he/she inserts or removes the lamp unit 30 into or from the housing 20. The length of the handle 36 is more preferably 100 mm to 400 mm so as to be easily gripped by a person and not to be an obstacle.

Note that the handle 36 may be bent or curved so as to be easily gripped by a person, or may be provided with a protrusion or a recess in a part thereof so that a person easily puts his/her hand or finger thereon. In addition, in a case where, for example, the plate material 32 has a portion on which a person puts his/her finger is formed on the plate material 32 in order to pull out the lamp unit 30 from the housing 20, the handle 36 may not be provided. Further, the handle 36 may be detachable from the housing 20.

FIG. 9 is a diagram illustrating a state in which the restriction member 33 is disassembled. The restriction member 33 in the present embodiment includes a base member 70, a first columnar support 71a, a second columnar support 71b, a first holding member 72a, and a second holding member 72b as illustrated in FIG. 9.

The base member 70 is provided so as to protrude in the +Y direction from the first main surface 32a of the plate material 32, and the first columnar support 71a is provided so as to protrude in the +Z direction. In addition, the base member 70 includes the second columnar support 71b partially extending in the +Z direction at a position farther to the +Y side with respect to the first columnar support 71a, that is, farther from the plate material 32.

The restriction member 33 includes the first holding member 72a and the second holding member 72b that hold the light-emitting tube 31c of the excimer lamp 31 between the first columnar support 71a and the second columnar support 71b. The first holding member 72a and the second holding member 72b hold and support the light-emitting tube 31c in such a manner that the end part of the light-emitting tube 31c of the excimer lamp 31 is placed on the first holding member 72a and the second holding member 72b is screwed and fixed to the first columnar support 71a and the second columnar support 71b.

In the present embodiment, the base member 70, the first columnar support 71a, and the first holding member 72a are formed of a ceramic material which is an insulating material, and the second columnar support 71b and the second holding member 72b are formed of a metal material. Regarding the second columnar support 71b and the second holding member 72b, specifically, the second columnar support 71b is formed of aluminum, and the second holding member 72b is formed of stainless steel.

In addition, the first holding member 72a is provided with a plate spring 71c as a conductive member made of beryllium copper which is a metal material as illustrated in FIG. 9. The plate spring 71c comes in contact with the first electrode 31a (not illustrated in FIG. 9) when the light-emitting tube 31c is placed.

Although the second columnar support 71b in the present embodiment is entirely formed of hard alumite, the second columnar support 71b may be only partially formed of a metal material so that the second electrode 31b and the second power supply portion 34b are electrically connected when supporting the excimer lamp 31.

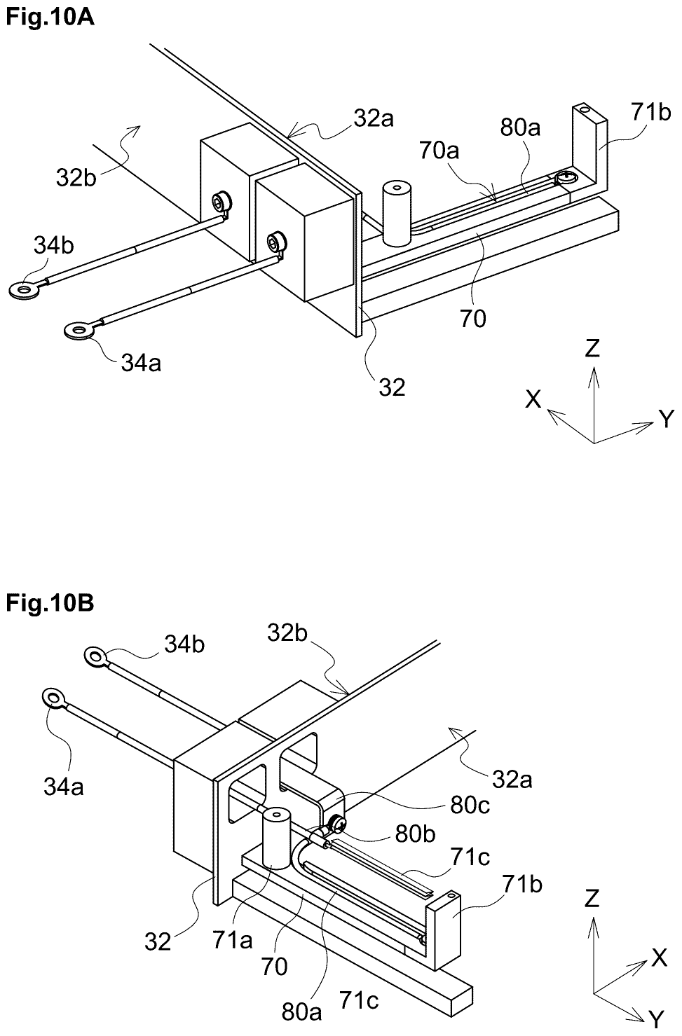

FIG. 10A is a diagram illustrating the periphery of the base member 70 in FIG. 9, and FIG. 10B is a diagram illustrating the periphery of the base member 70 in FIG. 9 when viewed from an angle different from that in FIG. 10A. FIGS. 10A and 10B do not illustrate the first holding member 72a and the second holding member 72b for convenience of description. In FIG. 10B, the first holding member 72a is not illustrated, and only the plate spring 71c is virtually illustrated so that a conduction path from the first power supply portion 34a can be recognized.

As illustrated in FIGS. 10A and 10B, a groove 70a in which a lead wire 80a is wired is formed in the base member 70. The lead wire 80a is wired in the groove 70a of the base member 70 to electrically connect the second columnar support 71b and the second power supply portion 34b. In the lamp unit 30 according to the present embodiment, a metal plate 80c is connected between the second power supply portion 34b and the lead wire 80a as illustrated in FIG. 10B due to the device configuration.

That is, when the first holding member 72a and the second holding member 72b hold the light-emitting tube 31c of the excimer lamp 31, the second columnar support 71b and the second holding member 72b come into contact with each other and are electrically connected. The base member 70 in the present embodiment is formed with the groove 70a for insertion of the lead wire 80a, but may be formed with a through hole for insertion of the lead wire 80a.

The plate spring 71c is a member formed by bending a plate material made of beryllium copper which is a metal material, and is electrically connected to the first power supply portion 34a via a lead wire 80b as illustrated in FIG. 10B.

With the above configuration, position adjustment of the excimer lamp 31 after mounting of the lamp unit 30 and complicated wiring connection work in the housing 20 are unnecessary. In addition, as compared with a case where work is performed by supporting only one end side of the light-emitting tube 31c, a load applied to an operator and the light-emitting tube 31c itself at the time of replacement of the excimer lamp 31 is reduced. Therefore, the replacement of the excimer lamp 31 is facilitated, and the risk of damaging the excimer lamp 31 is reduced.

The irradiation unit 10 in the present embodiment is mounted below the conveyance path 2 on which the workpiece W1 is conveyed in the ultraviolet irradiation device 1 as illustrated in FIG. 1, but may be mounted above the conveyance path 2 of the workpiece W1, for example.

### Other Embodiments

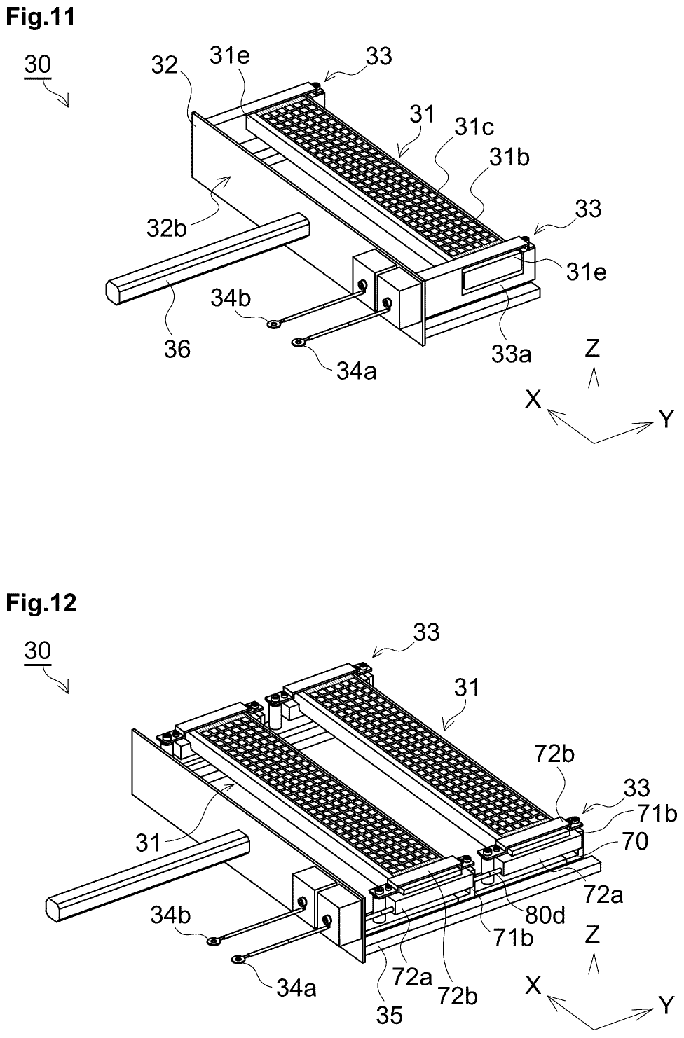

Other embodiments will now be described.

<1> FIG. 11 is a perspective view schematically illustrating a lamp unit 30 included in an irradiation unit 10 according to another embodiment. As illustrated in FIG. 11, the lamp unit 30 may be configured such that restriction members 33 include grasping portions 33a, protrude in the Y direction from a first main surface 32a of a plate material 32, and hold both end parts (31e, 31e) of a light-emitting tube 31c of an excimer lamp 31. In this configuration, the grasping portions 33a are made of an insulating material such as a ceramic material, and electrodes (32a, 32b) of the excimer lamp 31 and power supply portions (34a, 34b) are electrically connected using a lead wire, a metal plate, or the like (not illustrated) provided separately from the restriction members 33.

The above configuration can be employed in a case where a voltage applied to the excimer lamp is relatively low, and a leakage current or the like is not generated in the wiring tube even if the wiring in the housing 20 is slightly deviated.

<2> FIG. 12 is a perspective view schematically illustrating a lamp unit 30 included in an irradiation unit 10 according to still another embodiment. As illustrated in FIG. 12, a plurality of excimer lamps 31 may be mounted on the lamp unit 30. In this configuration, the lamp unit 30 includes, for example, restriction members 33 in which the length of base members 70 is adjusted according to the width of a region in which the excimer lamps 31 are mounted as illustrated in FIG. 12.

In the configuration illustrated in FIG. 12, a lead wire 80d for connecting plate springs 71c (not illustrated) mounted on the first holding members 72a provided for the excimer lamps 31 is provided. The second holding members 72b are connected to the corresponding second columnar supports 71b, and the second columnar supports 71b are connected by lead wires (not illustrated) wired inside the base members 70.

<3> The configurations of the irradiation unit 10, the lamp unit 30, and the lamp holder 30a described above are merely examples, and the present invention is not limited to the illustrated configurations.

### DESCRIPTION OF REFERENCE SIGNS

Ultraviolet irradiation device
2 Conveyance path
10 Irradiation unit
20 Housing
21 Insertion opening
22 Guide insertion portion
23 Light extraction portion
30 Lamp unit
30a Lamp holder
31 Excimer lamp
31a First electrode
31b Second electrode
31c Light-emitting tube
31d Reflective membrane
31e End part
31p Outer wall surface
31q Inner wall surface
32 Plate material
32a First main surface
32b Second main surface
33 Restriction member
33a Grasping portion
34a First power supply portion
34b Second power supply portion
35 Guide member
36 Handle
70 Base member
70a Groove
71a First columnar support
71b Second columnar support
71c Plate spring
72a First holding member
72b Second holding member
80a, 80b, 80d Lead wire
80c Metal plate
G1 Light-emitting gas
L1 Ultraviolet light
W1 Workpiece
W1a Irradiation surface

1. An irradiation unit comprising:
an excimer lamp that has a long shape extending in a first direction;
a lamp holder on which the excimer lamp is mounted;
a housing having an insertion opening and receiving the lamp holder through the insertion opening;
a light extraction portion provided in the housing and extracting ultraviolet light emitted from the excimer lamp mounted on the lamp holder to an outside of the housing;
a plate material provided on the lamp holder and closing the insertion opening;
a restriction member that restricts movement of the excimer lamp in the housing, the restriction member being formed so as to protrude from a first main surface located inside the housing among main surfaces of the plate material in a state where the plate material closes the insertion opening; and
a power supply portion that is provided on a side of a second main surface of the plate material located outside the housing and that supplies electric power to the excimer lamp in a state where the plate material closes the insertion opening.

2. The irradiation unit according to claim 1, wherein the excimer lamp includes a light-emitting tube having a pair of flat outer wall surfaces facing each other, and a first electrode and a second electrode that are formed on the pair of outer wall surfaces of the light-emitting tube so as to face each other across the light-emitting tube.

3. The irradiation unit according to claim 1, wherein
the restriction member includes:
a base member that protrudes from the first main surface of the plate material in a second direction that is a normal direction of the first main surface;
a first columnar support protruding from the base member in a third direction orthogonal to the first direction and the second direction;
a second columnar support protruding from the base member in a direction same as the direction in which the first columnar support protrudes at a position farther from the plate material than the first columnar support; and
a first holding member and a second holding member that hold an end part of the excimer lamp between the first columnar support and the second columnar support,
the second holding member being fixed so as to connect the first columnar support and the second columnar support.

4. The irradiation unit according to claim 3, further comprising:
a conductive member made of a metal material, the conductive member being held between the first holding member and the excimer lamp and coming in contact with a first electrode that is one of a pair of electrodes included in the excimer lamp; and
a lead wire that electrically connects the second columnar support and a second electrode different from the first electrode of the excimer lamp, the lead wire being wired inside a groove or a through hole formed in the base member,
wherein the first holding member is formed of a ceramic material, at least a part of the second holding member and the second columnar support is formed of a metal material, and
when the first holding member and the second holding member are fixed while holding the excimer lamp, a first power supply portion included in the power supply portion and the first electrode are electrically connected via the conductive member, and a second power supply portion that is different from the first power supply portion and that is included in the power supply portion and the second electrode are electrically connected via the second holding member, the second columnar support, and the lead wire.

5. The irradiation unit according to claim 1, wherein the plate material includes a handle protruding from the second main surface.

6. The irradiation unit according to claim 1, further comprising:
a guide insertion portion formed in the housing and extending in a second direction that is a normal direction of the first main surface; and
a guide member provided on the plate material and extending in the second direction, the guide member being inserted into the guide insertion portion to restrict movement of the lamp holder.

7. The irradiation unit according to claim 1, wherein the light extraction portion of the housing is covered with a material that transmits ultraviolet light emitted from the excimer lamp, and an inner space of the housing is enclosed by closing the insertion opening by the plate material due to insertion of the lamp holder.

8. A lamp unit comprising the excimer lamp and the lamp holder included in the irradiation unit according to any one of claims 1 to 7.

9. A lamp holder provided in the irradiation unit according to any one of claims 1 to 7.
